(19) United States
(12) Patent Application Publication
(10) Pub. No.: US 2010/0068467 A1
(43) Pub. Date: Mar. 18, 2010

(54) METHOD FOR TREATING SURFACE OF SUBSTRATE RESIN AND SUBSTRATE RESIN TREATED THEREBY

(75) Inventors: Young-Ah SONG, Suwon-si (KR); Jae-Woo Joung, Suwon-si (KR); Hyun-Chul Jung, Yongin-si (KR); In-Young Kim, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 12/434,177

(22) Filed: May 1, 2009

(30) Foreign Application Priority Data
Sep. 17, 2008 (KR) 10-2008-0091156

(51) Int. Cl. B32B 3/10; H05K 3/00

(52) U.S. Cl. 428/172; 427/98.8; 427/537

(57) ABSTRACT

It relates to a method for treating the surface of a printed circuit board resin and a printed circuit board resin treated thereby. The method may allows forming fine circuit patterns and improving the adhesive strength between metal patterns and the printed circuit board resin as well.

### CROSS-REFERENCE TO RELATED APPLICATIONS

This application claims the benefit of Korean Patent Application No. 10-2008-0091156 filed on Sep. 17, 2008, with the Korea Intellectual Property Office, the contents of which are incorporated here by reference in their entirety.

### BACKGROUND

1. Technical Field

It relates to a method for treating the surface of a printed circuit board resin and a printed circuit board resin treated thereby.

2. Description of the Related Art

Inkjet printing is a technology to print patterns onto a printed circuit board resin by ejecting metal ink through fine nozzles of an inknet head. Recently, there is a large demand for research on manufacturing printed circuit boards for electronic devices by employing the inkjet printing in response to need for low manufacturing cost. It is also allowed to manufacture metal nano inks having excellent dispersion stability with development of nano technologies.

Metal nanoparticles contained in such inks are suitable for forming circuit wirings on a printed circuit board, of which material is organic compounds, since they can be sintered at a low temperature of about 200° C.

Inket printing has allowed simplifying conventional processes for forming patterns on a printed circuit board and small quantity batch productions.

It is required to use a resin, which is able to stand against heat at a sintering temperature of printed nano metal particles of about 200° C., to form printed circuit patterns by the inkjet printing. An example of a resin includes a bismaleimide triazine resin including BT compounds which have high glass transition temperature.

However, high heat-resistant and thermoset resins such as BT resins have low adhesive strength with metal patterns in a conductive layer so that it may cause delamination between an insulating layer and a metal pattern layer during reliability tests such as thermal shock test.

In order to resolve this problem, there has been introduced a thin adhesive layer between a resin layer and a metal pattern layer. However, the thin adhesive layer formed between a resin layer and a metal pattern layer gets water-absorbed, which deteriorates adhesive strength and heat resistance.

Further, ink ejected from a nozzle of an inkjet head may spread on a resin layer, whereby it may be difficult to print fine and high density patterns.

Thus, a thin adhesive layer on a BT resin is coated and then circuit patterns are printed thereon in order to solve this problem. However, metal patterns printed thereon may be cracked due to different contraction rate between metal patters and the thin adhesive layer, whereby it may be difficult to be practically used.

Therefore, in order to print circuit patterns on a thermalset resin having high thermal stability by employing a digital manufacturing process such as inkjet printing, it is necessary to provide sufficient adhesive strength between the thermoset resin having high thermal stability and nano metal ink and provent from spreading of ink to print high dense patterns.

### SUMMARY

It is to provide a method for treating the surface of a printed circuit board resin and a printed circuit board resin treated thereby.

An aspect of embodiments is to provide a method for treating the surface of a printed circuit board resin, the method including: providing a printed circuit board resin; roughening the surface of the printed circuit board resin and forming heights and grooves on the surface; filling a filler into the grooves; forming a coating layer by coating the surface of the printed circuit board resin, where the grooves are filled with the filler, with a lyophobic material; and removing the filler filled in the grooves and the coating layer contacted to the filler filled in the grooves.

According to an embodiment, the method may further include removing the filler coated on the surface of the height when the filler is filled more than a volume of the groove and coats the surface of the height at the step of filling the filler into the grooves.

According to an embodiment, the step of roughening the surface of the printed circuit board resin and forming heights and grooves on the surface is performed by a plasma, etching or desmear method.

According to an embodiment, the filler is at least one chosen from silica having a particle size of less than 1 μm, titania having a particle size of less than 1 μm, sodium stearate nanoparticles, C16 to C19 hydrocarbon nanoparticles, aluminium nanoparticles, lidium nanoparticles, silver nanoparticles, copper nanoparticles and gold nanoparticles.

According to an embodiment, the lyophobic material is at least one chosen from at least one fluoro-based compound chosen from fluoro alkyl silane, heptadecafluoro-1,1,2,2-tetrahydrodecyl triethoxy silane, heptadecafluoro-1,1,2,2-tetrahydrodecyl trimethoxy silane, heptadecafluoro-1,1,2,2-tetrahydrodecyl trichloro silane, tridecafluoro-1,1,2,2-tetrahydrooctyl triethoxy silane, tridecafluoro-1,1,2,2-tetrahydrooctyl trimethoxy silane, tridecafluoro-1,1,2,2-tetrahydrooctyl trichloro silane, and trifluoropropyl trimethoxy silane; at least one silicone-based compound chosen from dimethyl polysiloxane, phenylmethyl polysiloxane, polydimethyl siloxane, vinyl silane and acrylate silane; and at least one fluoro carbon-based compound chosen from C₂F₆, C₆F₁₄, C₇F₁₆, C₈F₁₈, and C₉F₂₀.

Another aspect of embodiments is to provide a printed circuit board resin including: heights formed by roughening the surfaced of a printed circuit board resin; grooves formed by roughening the surfaced of a printed circuit board resin; and a lyophobic coating layer on the upper surface of the heights.

According to an embodiment, roughening the surface of the printed circuit board resin and forming heights and grooves on the surface is performed by a plasma, etching or desmear method.

According to an embodiment, the lyophobic coating layer is at least one chosen from: at least one fluoro-based compound chosen from fluoro alkyl silane, heptadecafluoro-1,1,2,2-tetrahydrodecyl triethoxy silane, heptadecafluoro-1,1,2,2-tetrahydrodecyl trimethoxy silane, heptadecafluoro-1,1,2,2-tetrahydrodecyl trichloro silane, tridecafluoro-1,1,2,2-tetrahydrooctyl triethoxy silane, tridecafluoro-1,1,2,2-tetrahydrooctyl trimethoxy silane, tridecafluoro-1,1,2,2-tetrahydrooctyl trichloro silane, and trifluoropropyl trimethoxy silane; at least one silicone-based compound chosen from dimethyl polysiloxane, phenylmethyl polysiloxane, polydimethyl siloxane, vinyl silane and acrylate silane; and at least one fluoro carbon-based compound chosen from C₂F₆, C₆F₁₄, C₇F₁₆, C₈F₁₈, and C₉F₂₀.

Additional aspects and advantages will be set forth in part in the description which follows, and in part will be obvious from the description, or may be learned by practice.

### BRIEF DESCRIPTION OF THE DRAWINGS

FIG. 1 illustrates a process for treating the surface of a printed circuit board resin according to an embodiment.

FIG. 2 illustrates a process for treating the surface of a printed circuit board resin according to another embodiment.

FIG. 3 illustrates a process for treating the surface of a printed circuit board resin according to further another embodiment.

FIG. 4 is a cross-sectional view of a printed circuit board resin according to further another embodiment.

FIG. 5 is a cross-sectional view of a printed circuit board resin where metal ink is printed according to further another embodiment.

FIG. 6a is a photograph of Example 1.

FIG. 6b is a photograph of Comparison Example 1.

FIG. 6c is a photograph of Comparison Example 2.

### DETAILED DESCRIPTION

While the present invention has been described with reference to particular embodiments, it is to be appreciated that various changes and modifications may be made by those skilled in the art without departing from the spirit and scope of the present invention, as defined by the appended claims and their equivalents. Throughout the description of the present invention, when describing a certain technology is determined to evade the point of the present invention, the pertinent detailed description will be omitted.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

The method for treating the surface of a printed circuit board resin and a printed circuit board resin treated thereby will be described below in more detail with reference to the accompanying drawings, in which those components are rendered the same reference number that are the same or are in correspondence, regardless of the figure number, and redundant explanations are omitted.

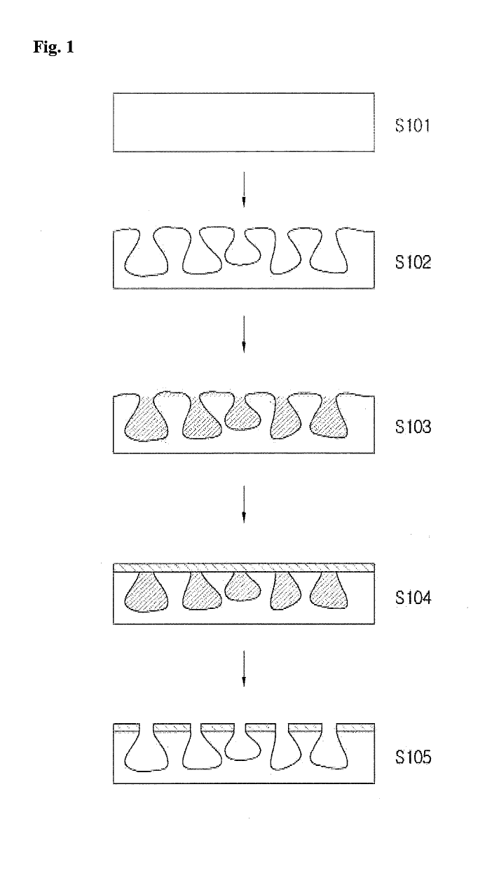

A method for treating the surface of a printed circuit board resin according to an embodiment may improve adhesive strength between the printed circuit board resin and metal ink and allow printing fine circuit patterns as well. The improvement of adhesive strength between the printed circuit board resin and metal ink may be provided by forming roughness of the surface of the printed circuit board resin and the forming fine circuit patterns may from a lyophobic coating. FIG. 1 shows an example.

As shown in FIG. 1, the surface of a printed circuit board resin may be treated by the following processes, including providing a printed circuit board resin (S101); roughening the surface of the printed circuit board resin and forming heights and grooves on the surface (S102); filling a filler into the grooves (S103); forming a coating layer by coating the surface of the printed circuit board resin, where the grooves are filled with the filler, with a lyophobic material (S104); and removing the filler filled in the grooves and the coating layer contacted to the filler filled in the grooves (S105).

Examples of the printed circuit board being suitable for the surface treatment of the printed circuit board resin may include a rigid type which is a general board, a flexible type, and a rigid-flexible type, etc. Any type of boards may be used without any limitation if it provides the same effect which the example boards do. A resin being used for the printed circuit board may be surface-treated by an embodiment herein.

Roughening the surface of a printed circuit board (S102) may be conducted by a physical or chemical method, for example plasma, etching or desmear method.

In the plasma method, roughness of the surface of a printed circuit board may be controlled by a kind of gas used during the surface treatment and density of energy, etc. Examples of gas may include inert gas such as nitrogen, argon, helium and the like.

Plasma is a partially or soley ionized gas of ions and electrons and is created when sufficient energy is provided into gas to break into electrons and ions. Free electrons from a cathode collide with gas molecules or gas atoms while moving with kinetic energy and energy generated at this moment ionizes gas molecules or gas atoms. Such plasmas may be created in a vacuum chamber. The plasma method may modify the surface of a printed circuit board resin more uniformly than other methods and improve physical and chemical adhesive strength between the printed circuit board resin and metal ink.

The etching method roughens the surface with an etching solution. The etching solution may be at least one chosen from an aqueous solution of KMnO₄ and an aqueous solution of NaMnO₄ and the like. But it is not limited thereto and may be any one without any limitation if it has an etching ability. Since the etching method roughens the surface of a resin by depositing a printed circuit board resin in the etching solution described above and removing molecules, the binding becomes weakened on the surface.

The desmear method is the removal of the resin, melted and smeared by frictional heat between drill bits and a printed circuit board resin across the inner-layer surface within the hole barrel during drilling.

Since this method can be used to creat roughness on the surface of a printed circuit board resin, it may be included as an example.

It is apparent that a physical etching method be used.

After roughening the surface of the printed circuit board resin and forming heights and grooves (S102), the grooves may be filled with a filler (S103).

Filling the filler into the grooves is to provent from coating of the surface of the grooves at the following coating step (S104). When the surface of the grooves is coated with a lyophobic material, the adhesion between the printed circuit board resin and metal ink becomes decreased than when it is not.

An example of the filler may include at least one chosen from silica having a particle size of less than 1 μm, titania having a particle size of less than 1 μm, sodium stearate nanoparticles, C16 to C19 hydrocarbon nanoparticles, aluminium nanoparticles, lidium nanoparticles, silver nanoparticles, copper nanoparticles and gold nanoparticles. However, it is not limited thereto and may be any material without any limitation if it is easily removable. An example of the filler being easily removable may be water soluble or pyrolytic material. A water soluble filler may be easily removable by a liquid solvent and a pyrolytic filler by heating so that it will be enough to be used as a filler.

Then, the surface of the printed circuit board resin, where the grooves are filled with the filler, may be coated with a lyophobic material to form a coating layer (S104).

A reason to form a lyophobic coating layer on the surface of the printed circuit board resin is to print fine circuit patterns. When metal ink is printed without forming the lyophobic coating layer, the metal ink may spread due to the rough surface created at the previous step, whereby it may be difficult to form fine circuit patterns. If the metal ink is printed on the rough surface of the printed circuit board resin, it may provide high adhesiveness but cause lowering resolution since the metal ink may spread on the surface of the resin due to increased surface energy of the board. Thus, when the coating layer is formed, it may lower the surface energy of the printed circuit board resin so that it prevents spreading of ink and results high resolution.

The lyophobic material may be at least one chosen from fluoro-based compounds or silicone-based compounds.

Examples of the lyophobic material may include a fluoro-based compound such as fluoro alkyl silane, heptadecafluoro-1,1,2,2-tetrahydrodecyl triethoxy silane, heptadecafluoro-1,1,2,2-tetrahydrodecyl trimethoxy silane, heptadecafluoro-1,1,2,2-tetrahydrodecyl trichloro silane, tridecafluoro-1,1,2,2-tetrahydrooctyl triethoxy silane, tridecafluoro-1,1,2,2-tetrahydrooctyl trimethoxy silane, tridecafluoro-1,1,2,2-tetrahydrooctyl trichloro silane, and trifluoropropyl trimethoxy silane; a silicone-based compound such as dimethyl polysiloxane, phenylmethyl polysiloxane, polydimethyl siloxane, vinyl silane and acrylate silane; and a fluoro carbon-based compound such as C₂F₆, C₆F₁₄, C₇F₁₆, C₈F₁₈, and C₉F₂₀. However, it is not limited thereto and may be any material if it has lyophobic characteristics.

Then, the filler filled into the grooves and the coating layer contacted to the filler filled into the grooves may be removed (S105).

The filler filled into the grooves and the coating layer contacted to the filler filled into the grooves may be removed by adding a solvent for water soluble fillers or heating for pyrolytic fillers.

Here, the lyophobic coating layer is formed only at the upper surface of the heights of the printed circuit board resin, which allows excellent adhesive strength between the printed circuit board resin and the metal ink and forming fine circuit patterns as well.

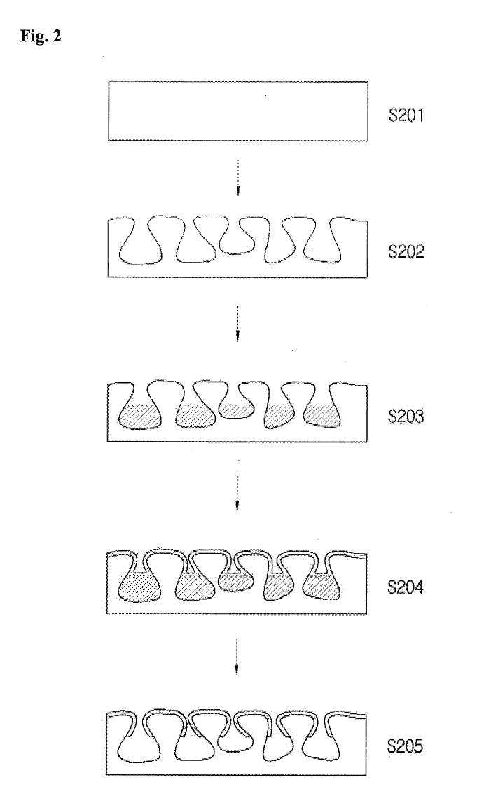

FIG. 2 shows the same process for treating the surface of the printed circuit board resin which includes providing a printed circuit board resin according to an embodiment (S101, S201); roughening the surface of the printed circuit board resin and forming heights and grooves on the surface (S102, S202); forming a coating layer by coating the surface of the printed circuit board resin, where the grooves are filled with the filler, with a lyophobic material (S104, S204); and removing the filler filled in the grooves and the coating layer contacted to the filler filled in the grooves (S105, S205), but has difference in the step of filling a filler (S203).

When the filler is filled, the filler may be filled into a part of the groove, which is not filled upto the height of the heights. As shown in S204 and S205 of FIG. 2, when the filler is not filed upto the height of the heights, the lyophobic coating layer is formed on the upper surface of the heights and a part of the grooves.

However, it is apparent that if the coating layer formed on a part of the grooves does not significantly deteriorate the adhesive strength between the metal ink and the printed circuit board resin, it may correspond to the purpose.

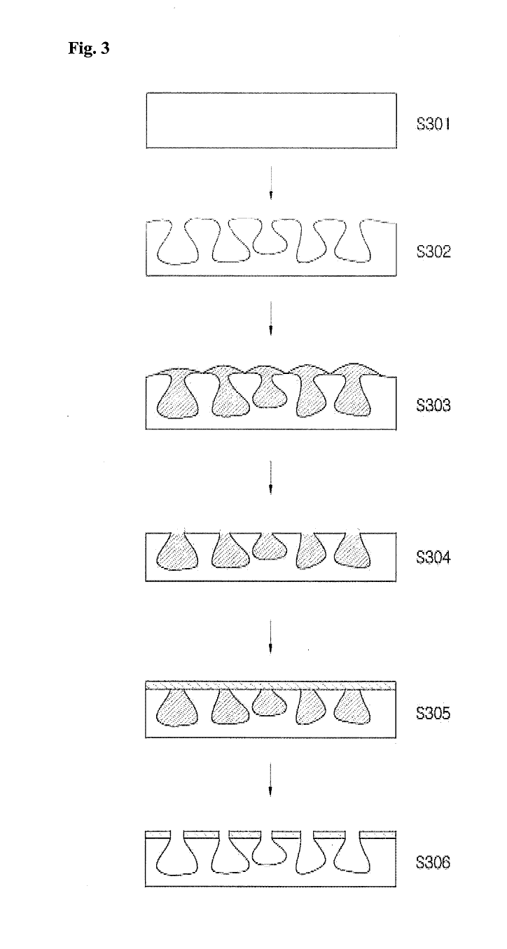

Another embodiment is shown in FIG. 3. The method for treating the surface of a printed circuit board resin may also include providing a printed circuit board resin (S101, S201, S301) and roughening the surface of the printed circuit board resin and forming heights and grooves on the surface (S102, S202, S302) but have some differences in the following steps.

In the step of filling a filler into the grooves (S303), the filler may be over-filled into the grooves and thus coat the upper surface of the heights. It may hinder from forming a coating layer on the upper surface of the heights. Thus, in this embodiment, it may include additionally removing the filler coated on the upper surface of the heights (S304).

A water soluble filler may be removed by wipping the surface of the heights with a wiper of which surface is covered with a solvent or a pyrolytic filler by heating selectively the surface of the heights.

Further processes including forming a coating layer by coating the surface of the printed circuit board resin, where the grooves are filled with the filler, with a lyophobic material (S104, S204, S305); and removing the filler filled in the grooves and the coating layer contacted to the filler filled in the grooves (S105, S205, S306), are the same as those of the previous embodiment described above.

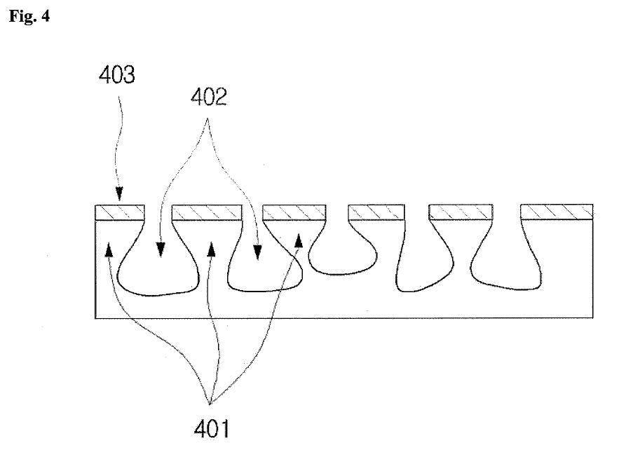

As shown in FIG. 4, there is provided a printed circuit board resin including heights formed by roughening the surfaced of a printed circuit board resin; grooves formed by roughening the surfaced of a printed circuit board resin; and a lyophobic coating layer on the upper surface of the heights.

The adhesive strength between metal ink and the printed circuit board resin may be increased due to roughness of the heights 401 and the grooves 402 and lyophobic characteristics of the lyophobic coating layer 403 may allow forming fine circuit patterns as well as described above.

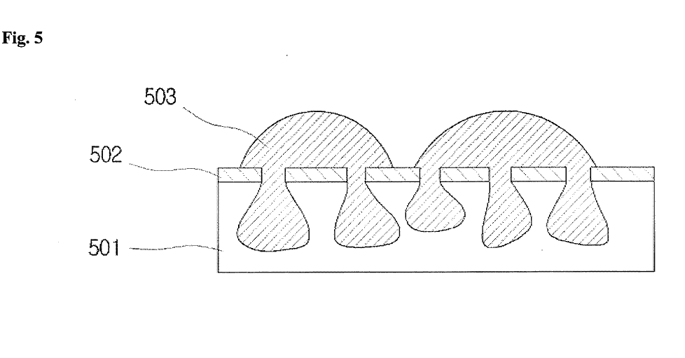

It may be noted from FIG. 5 that fine circuit patterns are formed by printing metal ink 503 on a printed circuit board resin 501 according to an embodiment. A lyophobic coating layer 502 is formed only on the upper surface of the heights so that it may allow forming fine circuit patterns by maintaining the adhesive between the metal ink 503 and the printed circuit board resin 502.

### Example 1

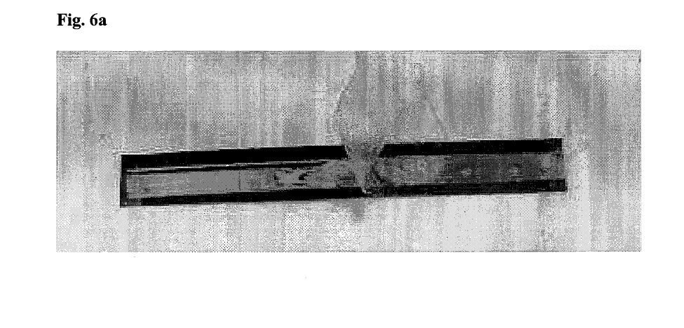

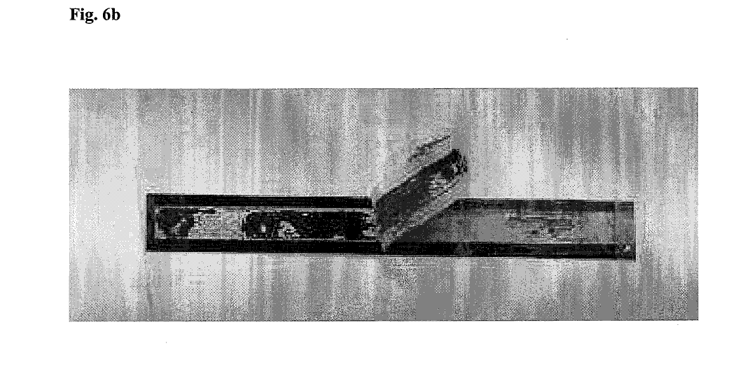

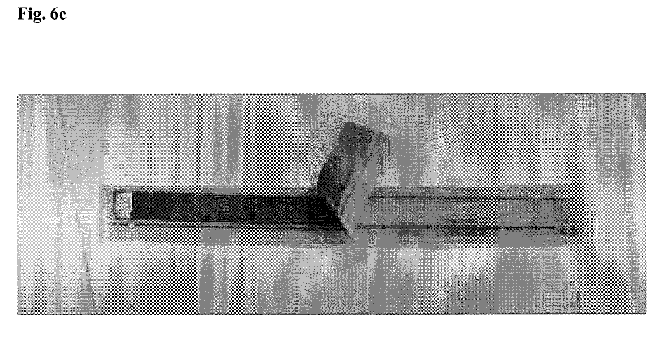

After roughening the surface of a printed circuit board resin, grooves were filled with Cu nanoparticles as a filler. A microfiber wiper covered with tetradecane solution removed the remain filler on the surface of the resin by wipping. The resin surface was lyophobic-processed by treating with plasma, submerged in a tetradecane solution, and conducted for ultrasonic wash to remove the filler filled in the grooves and the lyophobic layer contacted with the filler. Metal patterns were formed and it was taping-tested to determine the adhesive strength between the resin and the metal patterns. It was 0.45 kN/m at 900 peel test. The result was shown in FIG. 6a.

### Comparison Example 1

### When a Filler is Not Used

After roughening the surface of a printed circuit board resin, the resin including the grooves, which was not filled with a filler, was lyophobic-processed by treating with plasma. Metal patterns were formed and it was taping-tested. But most of metal patterns were removed. The adhesive was measured as 0.2 kN/m at 90° peel test. The result was shown in FIG. 6b.

### Comparison Example 2

### When Roughness was not Formed

The resin of which surface was not roughened was lyophobic-processed by treating with plasma. Metal patterns were formed and it was taping-tested. But all metal patterns were removed. The adhesive strength was measured as 0.005 kN/m at 90° peel test. The result was shown in FIG. 6c.

While it has been described with reference to particular embodiments, it is to be appreciated that various changes and modifications may be made by those skilled in the art without departing from the spirit and scope of the embodiment herein, as defined by the appended claims and their equivalents.

What is claimed is:

1. A method for treating surface of a printed circuit board resin comprising:
providing a printed circuit board resin;
roughening the surface of the printed circuit board resin and forming heights and grooves on the surface;
filling a filler into the grooves;
forming a coating layer by coating the surface of the printed circuit board resin, where the grooves are filled with the filler, with a lyophobic material; and
removing the filler filled in the grooves and the coating layer contacted to the filler filled in the grooves.

2. The method of claim 1, further comprising removing the filler coated on the surface of the height, when the filler is filled more than a volume of the groove and coats the surface of the height, at the step of filling the filler into the grooves.

3. The method of claim 1, wherein the step of roughening the surface of the printed circuit board resin and forming heights and grooves on the surface is performed by a plasma, etching or desmear method.

4. The method of claim 1, wherein the filler is at least one selected from the group consisting of silica having a particle size of less than 1 μm, titania having a particle size of less than 1 μm, sodium stearate nanoparticles, C16 to C19 hydrocarbon nanoparticles, aluminium nanoparticles, lidium nanoparticles, silver nanoparticles, copper nanoparticles and gold nanoparticles.

5. The method of claim 1, wherein the lyophobic material is at least one selected from the group consisting of:
at least one fluoro-based compound selected from the group consisting of fluoro alkyl silane, heptadecafluoro-1,1,2,2-tetrahydrodecyl triethoxy silane, heptadecafluoro-1,1,2,2-tetrahydrodecyl trimethoxy silane, heptadecafluoro-1,1,2,2-tetrahydrodecyl trichloro silane, tridecafluoro-1,1,2,2-tetrahydrooctyl triethoxy silane, tridecafluoro-1,1,2,2-tetrahydrooctyl trimethoxy silane, tridecafluoro-1,1,2,2-tetrahydrooctyl trichloro silane, and trifluoropropyl trimethoxy silane;
at least one silicone-based compound selected from the group consisting of dimethyl polysiloxane, phenylmethyl polysiloxane, polydimethyl siloxane, vinyl silane and acrylate silane; and
at least one fluoro carbon-based compound selected from the group consisting of C₂F₆, C₆F₁₄, C₇F₁₆, C₈F₁₈, and C₉F₂₀.

6. A printed circuit board resin comprising:
heights formed by roughening the surfaced of a printed circuit board resin;
grooves formed by roughening the surfaced of a printed circuit board resin; and
a lyophobic coating layer on the upper surface of the heights.

7. The printed circuit board resin of claim 6, wherein the roughening of the surface of the printed circuit board resin is conducted by a plasma, etching or desmear method.

8. The printed circuit board resin of claim 6, wherein the lyophobic coating layer is at least one selected from the group consisting of:
at least one fluoro-based compound selected from the group consisting of fluoro alkyl silane, heptadecafluoro-1,1,2,2-tetrahydrodecyl triethoxy silane, heptadecafluoro-1,1,2,2-tetrahydrodecyl trimethoxy silane, heptadecafluoro-1,1,2,2-tetrahydrodecyl trichloro silane, tridecafluoro-1,1,2,2-tetrahydrooctyl triethoxy silane, tridecafluoro-1,1,2,2-tetrahydrooctyl trimethoxy silane, tridecafluoro-1,1,2,2-tetrahydrooctyl trichloro silane, and trifluoropropyl trimethoxy silane;
at least one silicone-based compound selected from the group consisting of dimethyl polysiloxane, phenylmethyl polysiloxane, polydimethyl siloxane, vinyl silane and acrylate silane; and
at least one fluoro carbon-based compound selected from the group consisting of C₂F₆, C₆F₁₄, C₇F₁₆, C₈F₁₈, and C₉F₂₀.
